(19) United States
(12) Patent Application Publication
(10) Pub. No.: US 2008/0149378 A1
(43) Pub. Date: Jun. 26, 2008

(54) LIGHT SOURCE SIMULATING DEVICE

(75) Inventors: CHIH-CHAN GER, Tu-Cheng (TW); KO-WEN WANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/959,471

(22) Filed: Dec. 19, 2007

(30) Foreign Application Priority Data
Dec. 20, 2006 (CN) 200610157712.X

(51) Int. Cl. H05K 7/06

(52) U.S. Cl. 174/260

(57) ABSTRACT

A light source simulating device comprises a circuit board, at least a conductor and at least a resistor. The circuit board has a first surface. The conductor is disposed on the first surface of the circuit board. The resistor is also disposed on the first surface of the circuit board and connected in series to a high voltage end and a low voltage end of the light source simulating device by the conductor for simulating the light source. The light source simulating device in the present invention simulates the light source by the resistor and replaces the actual discharge lamps, which have lower cost, smaller test place and higher test reliability of the inverter.

### BACKGROUND OF THE INVENTION

1. Field of the Invention

The present invention relates to a light source simulating device, and more particularly to a light source simulating device which can be used in a backlight module of a liquid crystal display (LCD).

2. Description of Related Art

Conventionally, a liquid crystal display (LCD) panel uses discharge lamps, such as cold cathode fluorescent lamps (CCFLs), as a light source of a backlight system. In general, an inverter can provide AC signals to drive the discharge lamps. Typically, inverter manufacturers often assemble discharge lamps into the inverter, in order to detect performance of the inverter in response to electrical characteristics (current and/or voltage) of the discharge lamps.

However, because the discharge lamps are relatively expensive, it is undoubtedly a high cost task to assemble the discharge lamps into the inverter to detect the performance of the inverter. Further, test reliability is decreased because current flowing through the discharge lamps is prone to be influenced by environmental temperature. In addition, when the inverter is configured with large discharge lamps for testing, the needed test space is correspondingly increased.

### SUMMARY OF THE INVENTION

In one aspect of the present invention, a light source simulating device is provided. The light source simulating device comprises a circuit board, at least a conductor, and at least a resistor. The circuit board has a first surface. The conductor is disposed on the first surface of the circuit board. The resistor is also disposed on the first surface of the circuit board, and connected in series with a high voltage end and a low voltage end of the light source simulating device via the conductor, for simulating the light source.

Other advantages and novel features will become more apparent from the following detailed description when taken in conjunction with the accompanying drawings.

### BRIEF DESCRIPTION OF THE DRAWINGS

FIG. 1 is an isometric view of the light source simulating device according to an embodiment of the present invention;

FIG. 2 is an enlarged view of one light source set of the simulated light source shown in FIG. 1;

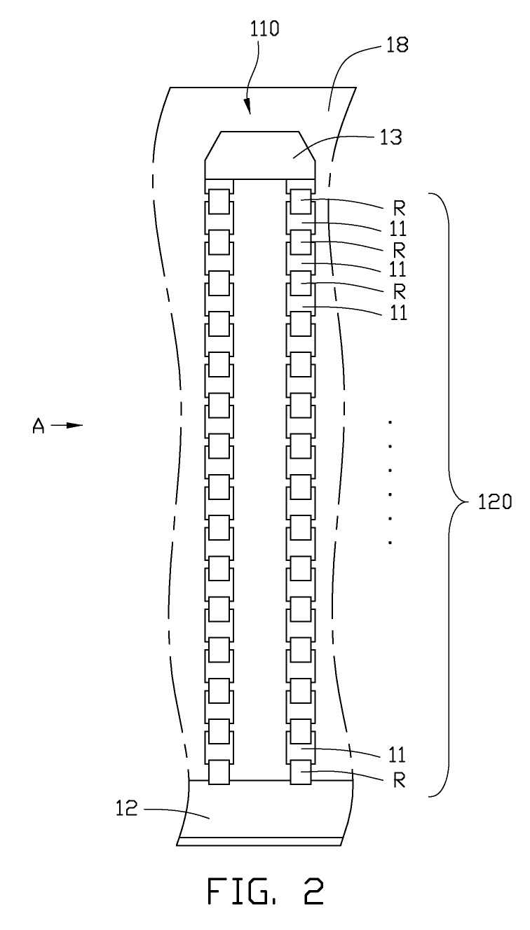

FIG. 3 is a side view along a direction A of the FIG. 2;

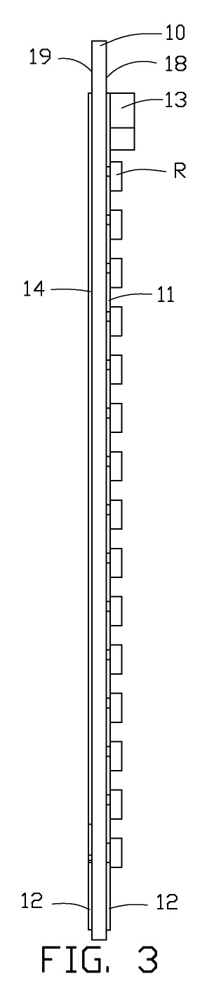

FIG. 4 is a back view of the FIG. 2;

FIG. 5 is an enlarged view of a portion V shown in the FIG. 4; and

FIG. 6 is an isometric view of the light source simulating device according to another embodiment of the present invention.

### DETAILED DESCRIPTION OF THE INVENTION

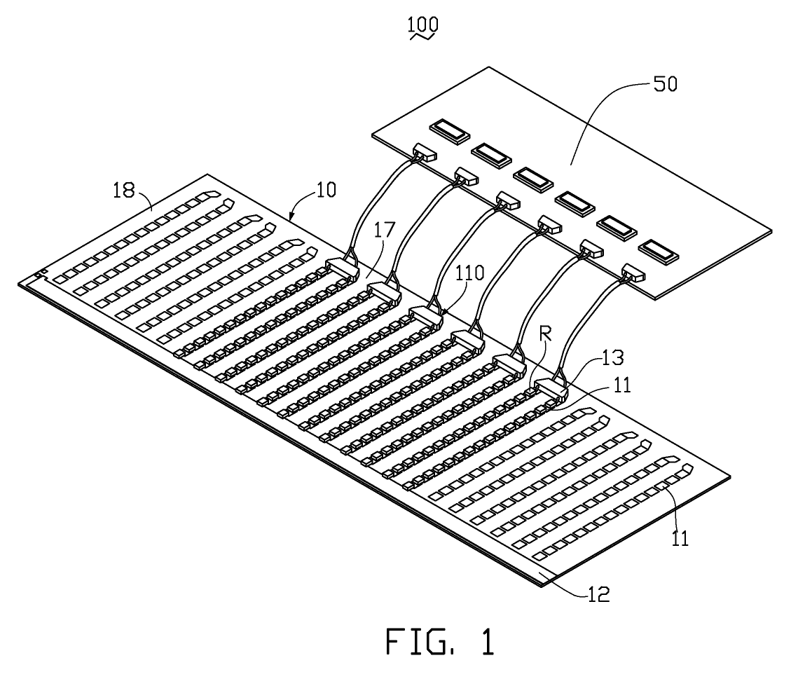

FIG. 1 is an isometric view of a light source simulating device 100 according to an embodiment of the present invention.

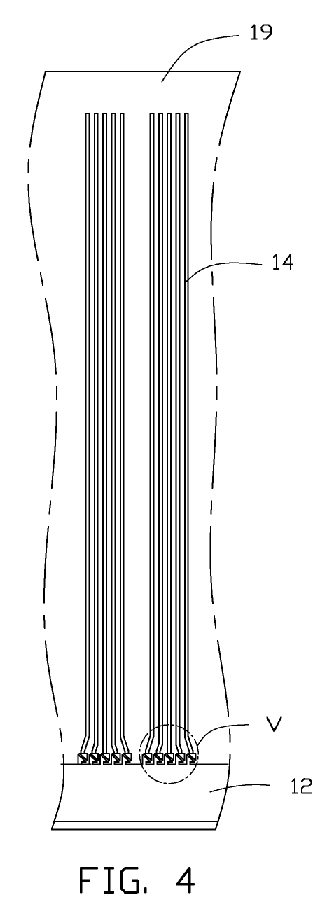

In this embodiment, the light source simulating device 100 is for testing an inverter, and comprises a circuit substrate or a circuit board 10, a plurality of electrical loads like resistors R, a plurality of first conductors and second conductors. In the preferred embodiment, the first conductors are first copper foils 11, and the second conductors are second copper foils 14 (referring to FIG. 4). The circuit board 10 has a plurality of connectors 13 disposed thereon, a first surface 18, and a second surface 19 (referring to FIG. 4). The resistors R and the first copper foils 11 are disposed on the first surface 18 of the circuit board 10, and the second copper foils 14 are disposed on the second surface 19 of the circuit board 10.

In the preferred embodiment, the light source simulating device 100 comprises six sets of simulated light sources 110, each set configured to simulate twelve discharge lamps. Each light source set 110 comprises two simulated light sources 120 and one connector 13. Each simulated light source 120 is composed of some of the resistors R in series with the first copper foils 11 between a high voltage end 17 and a low voltage end 12 of the simulating light source device 100. In the preferred embodiment, the high voltage end 17 of the light source simulating device 100 is connected to the connector 13, which is also connected to the inverter 50.

In one simulated light source 120, the first copper foils 11 and the resistors R disposed on the first surface 18 of the circuit board 10 are conductive, and the second copper foils 14 disposed on the second surface 19 are also conductive. In the preferred embodiment, each simulated light source 120 corresponds to five second copper foils 14 (referred to FIG. 4). In addition, two conductors are disposed closely to each other and filled with insulative material, forming a capacitor. Accordingly, the second copper foils 14 disposed on the second surface 19, the first copper foils 11 disposed on the first surface 18 and the resistors R disposed on the first surface 18 co-form a plurality of capacitors, in order to simulate stray capacitance of a light source, which increases the inverter test reliability.

In the preferred embodiment, widths of the first copper foils 11 are the same, and width of one first copper foil 11 is greater than that of one second copper foil 14. In addition, the low voltage ends 12 of the light source simulating device 100 are grounded, the resistors R are surface mounting device (SMD) components.

In other embodiments of the present invention, the number of the second copper foils 14 can be increased or decreased. When the width of each first copper foil 11 is fixed, and the more second copper foils 14 there are, overlapping between the conductor of the first surface 18 and the conductor of the second surface 19 are bigger. Therefore, the capacitance between the first surface 18 and the second surface 19 is greater. In the other words, the capacitance of the disperse capacitors are directly affected by the number and the width of the second copper foils 14. Similarly, the resistors R could be dip resistors, printed resistors, or combination of the dip resistors and the SMD components. The conductors could also be printed resistors, with values less than that of the resistors R.

In the preferred embodiment, phase of signals received by the high voltage end of adjacent simulated light sources 120 can be same or different. The low voltage end 12 of the simulating light source 100 is connected to a feedback circuit (not shown), for feeding back current flowing through the light source.

In addition, when the value of the resistors R is increased, the voltage of the simulated light source 120 is also increased. Therefore, the light source simulating device 100 can simulate large discharge lamps by increasing the value of the resistors R, without increasing the amount of space needed for testing. Because the simulated light sources 120 are hardly affected by temperature, reliability of inverter testing is increased.

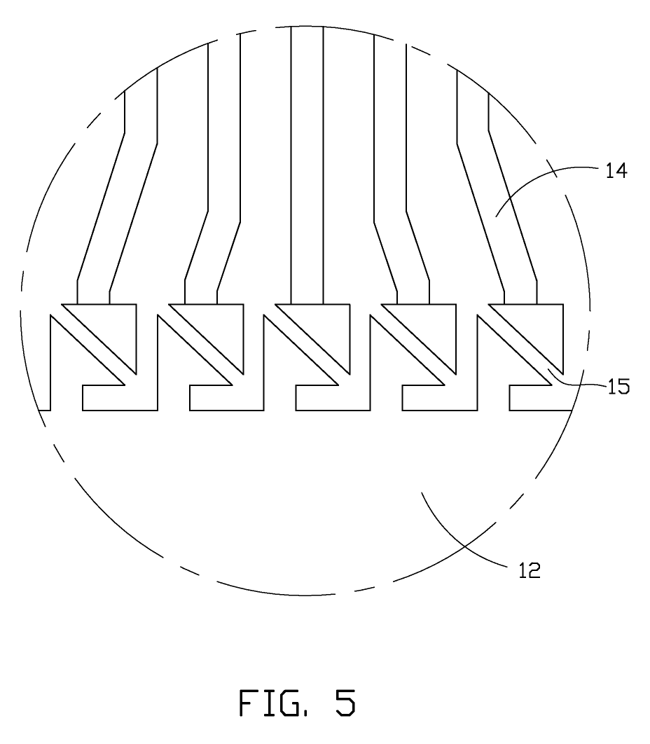

FIG. 5 is an enlarged view of a portion V part of FIG. 4 in the present invention. The gap 15 is formed via the second copper foils 14 and the low voltage end 12. When the solder is filled in the gap 15, a short circuit is formed between the second copper foils 14 and the low voltage end 12, which leads to a plurality of capacitors being connected in parallel, and the capacitance of the simulated light source 120 is increased. In the preferred embodiment, the more gaps 15 that are filled, the greater the capacitance of the simulated light source 120. With the increasing of the capacitance, the phase difference between the voltage and current of the simulated light source 120 can be increased. Therefore, the phase of the voltage and the current is adjusted by the gap between the second copper foils 14 and the low voltage end being filled or not.

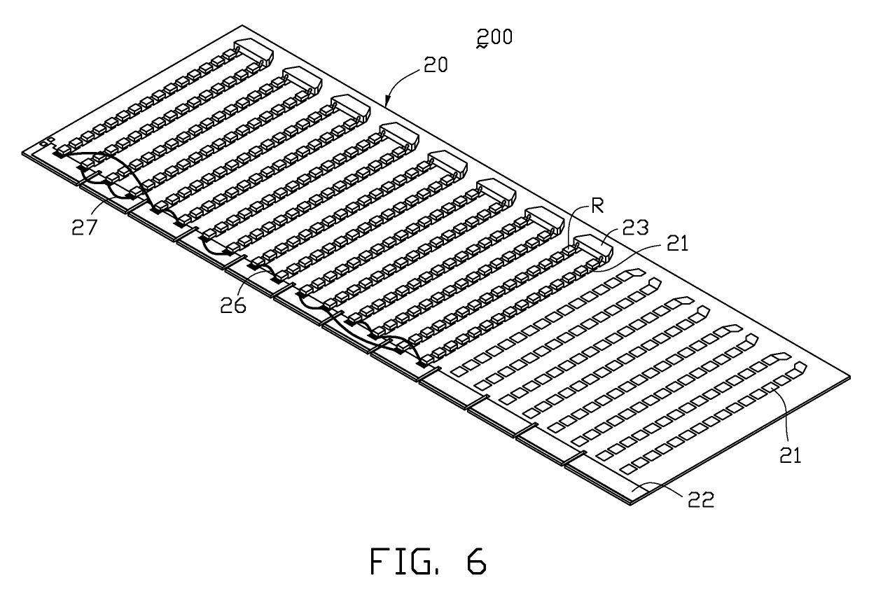

FIG. 6 is an isometric view of the light source simulating device 200 in another embodiment of the present invention. The light source simulating device 200 is substantially the same as the light source simulating device 100 in FIG. 1 with a difference being: in the light source simulating device 200, all the low voltage ends receiving the positive high voltage signals are connected with each other via a first line 26, all low voltage ends receiving the negative high voltage signals are connected with each other via a second line 27. According to requirement of the test, the first line 26 and the second line 27 are respectively connected to different ends of the feedback circuit (not shown), for feeding back current flowing through the light source. In the embodiment of the present invention, the light source simulating device 200 simulates sixteen discharge lamps.

In the present invention, the light source simulating device simulates the light source via a plurality of resistors, and simulates the disperse capacitors via a plurality of capacitors formed between the first surface and the second surface of the circuit board, thereby lowering testing cost, reducing space requirements for testing, and providing higher inverter test reliability.

What is claimed is:

1. A light source simulating device, comprising:
a circuit board having a first surface;
at least a conductor disposed on the first surface of the circuit board; and
at least a resistor disposed on the first surface of the circuit board and connected in series to a high voltage end and a low voltage end of the light source simulating device via the conductor, for simulating the light source.

2. The light source simulating device as recited in claim 1, wherein the circuit board further has a second surface, and at least one another conductor is disposed thereon, the another conductor of the second surface and the conductor, the resistor of the first surface are formed a plurality of capacitors, for simulating disperse capacitors of the light source.

3. The light source simulating device as recited in claim 2, wherein both of the conductor and the another conductor is copper foil.

4. The light source simulating device as recited in claim 2, wherein a gap is formed between the another conductor and the low voltage end.

5. The light source simulating device as recited in claim 2, wherein width of each conductor are the same.

6. The light source simulating device as recited in claim 5, wherein the width of the conductor is greater than that of the another conductor.

7. The light source simulating device as recited in claim 1, wherein the resistors are printed resistors, SMD (Surface Mounting technology Device) components, dip resistors, or combination of SMD components and dip resistors.

8. The light source simulating device as recited in claim 7, wherein the conductor is the printed resistor, and resistor value of the conductor is less than that of the resistor.

9. The light source simulating device as recited in claim 1, wherein the low voltage end is grounded.

10. The light source simulating device as recited in claim 1, further comprising a plurality of connectors disposed on the first surface of the circuit board, and connected to the high voltage end of the light source simulating device.

11. A device for simulating light sources, comprising:
a circuit substrate defining a surface thereon, a high voltage end and a low voltage end of a simulated light source being respectively defined at two opposite sides of said surface;
at least one conductor discretely disposed on said surface of said circuit substrate between said high voltage end and said low voltage end of said simulated light source; and
at least one electrical load used for simulating said simulated light source being electrically connectable in series between said high voltage end and said low voltage end of said simulated light source via said at least one conductor.

12. The device as recited in claim 11, wherein said circuit substrate defines another surface opposite to said surface thereof, and at least one another conductor is disposed on said another surface, said at least one another conductor on said another surface oppositely corresponds to said at least one conductor on said surface so as to correspondingly form at least one capacitor for simulating disperse capacitors of said simulated light source.

13. The device as recited in claim 11, wherein said at least one electrical load is a resistor.

14. A device for simulating light sources, comprising:
a circuit substrate defining a first surface and a second surface opposite to said first surface thereon, a high voltage end and a low voltage end of a simulated light source being respectively defined at two opposite sides of said first surface; and
at least one conductor discretely disposed on said first surface of said circuit substrate between said high voltage end and said low voltage end of said simulated light source, said at least one conductor being electrically connectable between said high voltage end and said low voltage end of said simulated light source by electrically connecting with at least one electrical load in series between said high voltage end and said low voltage end for simulating said simulated light source, and simultaneously forming at least one capacitor for simulating disperse capacitors of said simulated light source by correspondingly spacing from at least one another conductor disposed on said second surface.
